(19) United States
(12) Patent Application Publication
(10) Pub. No.: US 2025/0255081 A1
(43) Pub. Date: Aug. 7, 2025

(54) DISPLAY DEVICE

(71) Applicant: Innolux Corporation, Miaoli County (TW)

(72) Inventors: Chih-Lung Lin, Miaoli County (TW); Yung-Hsun Wu, Miaoli County (TW)

(73) Assignee: Innolux Corporation, Miaoli County (TW)

(21) Appl. No.: 19/026,377

(22) Filed: Jan. 17, 2025

Related U.S. Application Data
(60) Provisional application No. 63/550,605, filed on Feb. 7, 2024.

(30) Foreign Application Priority Data
Oct. 28, 2024 (CN) 202411513622.4

(51) Int. Cl. H10H 29/85; G09G 3/00; G09G 3/32; G09G 3/3208; H10H 29/855

(52) U.S. Cl. CPC H10H 29/858; G09G 3/32; H10H 29/855; G09G 3/003; G09G 3/3208; G09G 2320/041; G09G 2320/0626; G09G 2360/144

(57) ABSTRACT

A display device including a display panel, a heat dissipation element, and a light adjustment structure. The display panel has a light emitting side and a non-light emitting side and includes multiple light emitting units and multiple light concentration units. Each of the light emitting units corresponds to one of the light concentration units. The heat dissipation element is disposed at the non-light emitting side of the display panel, and includes multiple light control units. Each of the light control units corresponds to at least two of the light emitting units.

### CROSS-REFERENCE TO RELATED APPLICATION

This application claims the priority benefits of U.S. provisional application Ser. No. 63/550,605, filed on Feb. 7, 2024, and China application serial no. 202411513622.4, filed on Oct. 28, 2024. The entirety of each of the above-mentioned patent applications is hereby incorporated by reference herein and made a part of this specification.

### BACKGROUND

### Technical Field

The disclosure relates to an electronic device, and in particular to a display device.

### Description of Related Art

With the booming electronics industry, various applications for display devices have emerged. However, the problems faced by display devices are different in different applications. Therefore, there is a need for continuous improvement of various display devices.

### SUMMARY

The disclosure provides a display device, capable of helping reduce or avoid problems such as failure or damage caused by overheating.

The disclosure is directed to a display device, including a display panel, a heat dissipation element, and a light adjustment structure. The display panel has a light emitting side and a non-light emitting side, and includes multiple light emitting units and multiple light concentration units, where each of the light emitting units corresponds to one of the light concentration units. The heat dissipation element is disposed on the non-light emitting side of the display panel. The light adjustment structure is disposed on the light emitting side of the display panel and includes multiple light control units, where each of the light control units corresponds to at least two of the light emitting units.

According to the display device of some embodiments of the disclosure, heat emitted by the display panel can be dissipated by the heat dissipation element located on the non-light emitting side of the display panel, thereby helping to reduce or avoid problems such as failure or damage caused by overheating. The display panel can be controlled to regulate a display brightness or adjust a display image in response to the external environment, thereby providing a good display effect. In addition, the light emitting unit of the display panel and the light concentration unit can be disposed corresponding to the light adjustment structure, so that the display panel can be configured to achieve three-dimensional images or multiple depth-of-field display effects. In some embodiments, the image displayed by the display panel can also be adjusted according to objects in the environment to provide a display effect that meets the needs.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 is a schematic diagram of a display device according to an embodiment of the disclosure.

FIG. 2 is a schematic diagram of a light concentration unit according to an embodiment of the disclosure.

FIG. 3 is a schematic diagram of an arrangement relationship between a light emitting unit, a light concentration unit, and a light adjustment structure in the display device according to some embodiments of the disclosure.

FIG. 4 is a partial cross-sectional schematic diagram of a display device according to an embodiment of the disclosure.

FIG. 5 is a partial cross-sectional schematic diagram of a display device according to an embodiment of the disclosure.

FIG. 6 is a partial cross-sectional schematic diagram of a display device according to an embodiment of the disclosure.

FIG. 7 is a schematic diagram of the application of display device in this disclosure.

FIG. 8 is a block diagram of a display device according to an embodiment of the disclosure.

FIG. 9 is a block diagram of a display device according to an embodiment of the disclosure.

FIG. 10 is a block diagram of a display device according to an embodiment of the disclosure.

### DESCRIPTION OF THE EMBODIMENTS

Reference will now be made in detail to the exemplary embodiments of the disclosure, examples of which are illustrated in the accompanying drawings. Whenever possible, the same reference numerals are used in the drawings and descriptions to refer to the same or similar parts.

The ordinal numbers used in the specification and claims, such as “first” and “second”, are used to modify elements, do not in themselves imply or represent any prior ordinal sequence for such element(s), nor do they indicate any order between one element and another, or any order in the manufacturing process. The use of these ordinal numbers is solely for the purpose of clearly distinguishing between elements bearing the same nomenclature. Claims and specification may not use identical terminology. Accordingly, the first component described in the specification may be referred to as the second component in the claims.

Certain words are used throughout the specification and claims to refer to specific elements. Those skilled in the art understand that electronic device manufacturers may refer to the same element by different names. This article is not intended to differentiate between elements that have the same function but have different names. In the following specification and claims, words such as “comprise”, “include”, and “have” are open-ended words, so they should be interpreted as meaning “including but not limited to . . . ”. Therefore, when the terms “comprise”, “include”, and/or “have” are used in the description of the disclosure, they specify the presence of the corresponding features, regions, steps, operations, and/or components, but do not exclude the presence of one or more of corresponding features, regions, steps, operations and/or components.

In this disclosure, when one structure (or layer, component, substrate) is described as being “on” or “above” another structure (or layer, component, substrate), it may refer to instances where the two structures are adjacent and directly connected, or it may refer to instances where the two structures are adjacent but not directly connected. In the latter case, there is at least one intervening structure (or intervening layer, intervening component, intervening substrate, intervening spacing) between the two structures. The lower surface of one structure is adjacent to or directly connected to the upper surface of the intervening structure, while the upper surface of the other structure is adjacent to or directly connected to the lower surface of the intervening structure. The intervening structure may be composed of a single layer or multiple layers, and may be a physical or non-physical structure, without limitation. In this disclosure, when a structure is described as being “on” another structure, it may refer to the structure being “directly” on the other structure, or “indirectly” on the other structure, meaning that there may be at least one intervening structure between the structure and the other structure.

It should be understood that when a component or layer is described as “connected to” another component or layer, it may be directly connected to the another component or layer, or there may be intervening components or layers present. When a component is described as “directly connected to” another component or layer, there are no intervening components or layers present. Furthermore, when a component is described as “coupled to” another component (or a variant thereof), it can be directly connected to the another component, or indirectly connected (e.g., electrically connected) to the another component through one or more intervening components.

The electrical connection or coupling described in this disclosure can refer to direct connection or indirect connection. In the case of direct connection, the end points of the elements on two circuits are directly connected or connected to each other with a conductor line segment, and in the case of indirect connection, there are switches, diodes, capacitors, inductors, resistors, other suitable elements, or combinations of the above elements between the end points of the elements on the two circuits, but are not limited thereto.

In the disclosure, the thickness, length, and width can be measured using an optical microscope, and the thickness can be measured using cross-sectional images in an electron microscope, but is not limited thereto. In addition, there may be a certain amount of error between any two values or directions used for comparison. In addition, the terms “approximately,” “substantially,” or “generally” mentioned in this disclosure generally mean falling within 10% of a given value or range. Furthermore, the expressions “the given range is the first value to the second value” and “the given range falls within the range of the first value to the second value” mean that the given range includes the first value, the second value, and other values between them.

In the disclosure, various embodiments described below may be mixed and matched without departing from the spirit and scope of the disclosure. For example, some features of one embodiment may be combined with some features of another embodiment to form another embodiment.

The electronic device of the disclosure may include, for example, a display device, a sensing device, an antenna device, a touch device, a packaging device, a splicing device, or other suitable electronic devices, but is not limited thereto. The display device disclosed in this disclosure can be any type of display device, such as a self-illuminating display device, a non-self-illuminating display device, or a transparent display device. The self-luminous display device may include a light emitting diode, a light conversion layer, or other suitable materials, or a combination of the above, but is not limited thereto. The light emitting diode may include, for example, an organic light emitting diode (OLED), a sub-millimeter light emitting diode (mini LED), a micro-light emitting diode (micro LED), or a quantum dot light emitting diode (quantum dot LED, which can include QLED, QDLED), but is not limited thereto. The light conversion layer may include, for example, fluorescence, phosphor, Quantum Dot (QD), other suitable materials, or a combination of the above, but is not limited thereto. The non-self-luminous display devices may include liquid crystal display devices, but is not limited thereto. The sensing device may be, for example, a sensing device for detecting capacitance changes, light, heat energy or ultrasonic waves, but is not limited thereto. The sensing device may include, for example, a biosensor, a touch sensor, a fingerprint sensor, other suitable sensors, or a combination of the above types of sensors. The antenna device may be, for example, a liquid crystal antenna or other types of antennas, but is not limited thereto. The splicing device may include, for example, a splicing display device or a splicing antenna device, but is not limited thereto. In addition, the appearance of the electronic device may be, for example, a rectangle, a circle, a polygon, a shape with curved edges, a curved surface, or other suitable shapes. The electronic device can have peripheral systems such as drive system, control system, light source system, shelf system. The electronic device may include an electronic unit, where the electronic unit may include passive elements and active elements, such as capacitors, resistors, inductors, diodes, transistors, sensors. It should be noted that the electronic device of the disclosure can be various combinations of the above devices, but is not limited thereto.

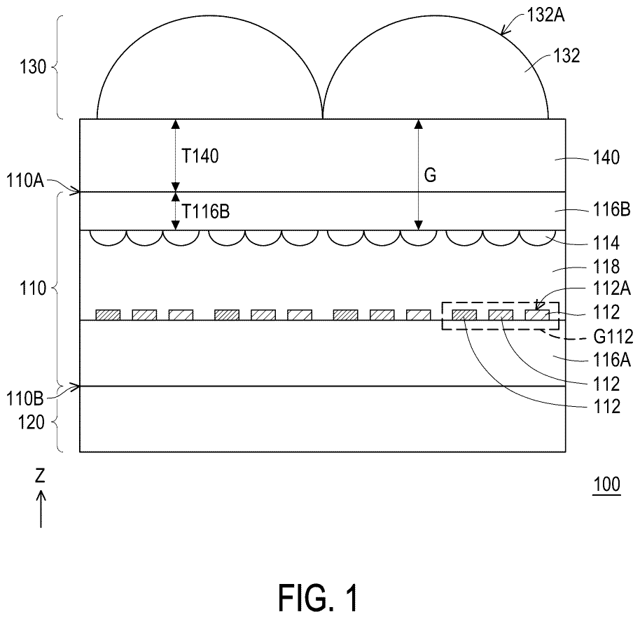

FIG. 1 is a schematic diagram of a display device according to an embodiment of the disclosure. In FIG. 1, a display device 100 basically includes a display panel 110, a heat dissipation element 120, and a light adjustment structure 130. The display panel 110 has a light emitting side 110A and a non-light emitting side 110B, where the light emitting side 110A and the non-light emitting side 110B may be opposite sides to each other. The heat dissipation element 120 is disposed on the non-light emitting side 110B of the display panel 110, and the light adjustment structure 130 is disposed on the light emitting side 110A of the display panel 110. In this way, the heat dissipation element 120 and the light adjustment structure 130 are disposed on opposite sides of the display panel 110, and the display panel 110 is disposed between the heat dissipation element 120 and the light adjustment structure 130, where the display panel 110 emits display light toward the light adjustment structure 130. The light adjustment structure 130 can be used to adjust the path of the display light of the display panel 110 to present the required display image, and the heat dissipation element 120 can be used to dissipate the heat emitted by the display panel 110 during operation to ensure the working efficiency of the display panel 110.

The display panel 110 includes multiple light emitting units 112 for emitting light to display images and multiple light concentration units 114 for adjusting light divergence angles, and each of the light emitting units 112 corresponds to one of the light concentration units 114. A light emitting surface 112A of each light emitting unit 112 is disposed toward one of the light concentration units 114, which allows the light emitted by each light emitting unit 112 to be mainly emitted toward the corresponding light concentration unit 114. The individual light concentration unit 114 may include lens, meta lens, condenser reflector, or the like, and the individual light concentration unit 114 may reduce the divergence angle of incident light. In other words, the light concentration unit 114 can adjust the light emitted by the light emitting unit 112 to emit it in a more concentrated form.

The light emitting units 112 may be light emitting diodes, such as micro-light emitting diodes, sub-millimeter light emitting diodes, organic light emitting diodes, or the like. The light emitting diodes used as the light emitting units 112 may include a variety of light emitting diodes for emitting different colors. For example, the light emitting diodes used as the light emitting units 112 may include red light emitting diodes, green light emitting diodes, and blue light emitting diodes, but are not limited thereto. Light emitting diodes of different colors can be implemented by using different light emitting chips or by using the light emitting chips with different filter materials and/or wavelength conversion materials (such as quantum dots). In some embodiments, the light emitting units 112 of three different colors may form a light emitting unit group G112. The light concentration unit 114 can also be set in groups corresponding to the layout of the light emitting units 112, but is not limited thereto.

The light adjustment structure 130 includes multiple light control units 132, and each of the light control units 132 corresponds to at least two of the light emitting units 112. In some embodiments, the individual light control unit 132 may be lens-shaped (including hemispherical lens, semi-cylindrical lens, etc.). In some embodiments, the individual light control unit 132 may be meta lens, lenticular lens, or the like. FIG. 1 illustrates, by way of example, the individual light control unit 132 as lens-shaped and a light exit surface 132A of the individual light control unit 132 with an arc profile in cross-sectional view. In some embodiments, the light exit surface 132A of the individual light control unit 132 may be composed of multiple tiny planes with different tilt angles and orientations. When viewing the projection of individual components in a thickness direction Z, each of the light control units 132 may overlap at least two of the light emitting units 112. For example, each of the light control units 132 may overlap 2×2 or more (e.g., more than 16) light emitting units 112, but is not limited thereto. Each of the light control units 132 is used to control the light emitting path so that the light emitted by the corresponding light emitting units 112 is emitted in a set direction, thereby achieving a required display effect. For example, under the setting of the light adjustment structure 130, the light emitted by the light emitting units 112 can be focused at different focus positions to form corresponding images at different focus positions, which can be used to realize display effect of augmented reality. In some embodiments, the display device 100 may be a head-up display device, but is not limited thereto.

In some embodiments, the display panel 110 further includes a first substrate 116A, a second substrate 116B, and a light-transmitting layer 118. The first substrate 116A and the second substrate 116B are disposed opposite to each other. Multiple light emitting units 112 are disposed on the first substrate 116A and are located between the first substrate 116A and the second substrate 116B. Multiple light concentration units 114 are disposed on the second substrate 116B and are located between the first substrate 116A and the second substrate 116B. The light-transmitting layer 118 is disposed between the light emitting units 112 and the light concentration units 114. The light emitting units 112 may be located between the first substrate 116A and the light-transmitting layer 118, and the light concentration units 114 may be located between the second substrate 116B and the light-transmitting layer 118.

The first substrate 116A is used to carry the light emitting unit 112. Although not shown in FIG. 1, the first substrate 116A may include a substrate body and a driving structure disposed on the substrate body, where the driving structure may include power circuits and pixel circuits to provide power and driving signals required by the light emitting unit 112. The material of the substrate body can be glass, quartz, organic polymers, opaque/reflective materials (such as conductive materials, metals, wafers, ceramics, or other applicable materials), other applicable materials, a single layer of one of the above materials or a stack of multiple layers of the above materials. In some embodiments, the first substrate 116A may be a circuit board, but is not limited thereto.

The second substrate 116B and the light-transmitting layer 118 can at least allow the light emitted by the light emitting units 112 to pass through. In order to display an image viewable by human eyes, the second substrate 116B and the light-transmitting layer 118 are at least transparent to visible light. For example, the material of the second substrate 116B may include glass, transparent plastic materials, and other materials that can be used as transparent substrates. The light-transmitting layer 118 is disposed around the light concentration unit 114, and the light-transmitting layer 118 may include a vacuum layer, an air layer, or other transparent material layers. In some embodiments, the light-transmitting layer 118 may include a stack of multiple layers/materials, such as a combination including organic materials, photoresist materials, adhesive materials (optical adhesives, light-transmitting resins, etc.), and low refractive index materials. In some embodiments, the refractive index of the light-transmitting layer 118 may be less than the refractive index of the light concentration unit 114. In some embodiments, the difference between the refractive index of the light-transmitting layer 118 and the refractive index of the light concentration unit 114 may be greater than 0.5. In some embodiments, the refractive index of the light-transmitting layer 118 may be less than 1.4, but is not limited thereto. In some alternative embodiments, the light-transmitting layer 118 includes multiple light-transmitting regions, each of which may function to define a light path. For example, the display device includes multiple light-blocking structures. The light-blocking structures separate the light-transmitting layer 118 into multiple light-transmitting regions, allowing only light within specific light emitting angle ranges to pass through. The light-blocking structure may be disposed correspondingly between adjacent light emitting units 112, for example. In this way, it is helpful to concentrate the light emitted by the light emitting units 112 in a limited range of light emitting angles, and/or reduce the cross talk of light between the light emitting units 112. In other words, under the arrangement of the light-blocking structure, the light emitted by the individual light emitting unit 112 can travel to the corresponding one of the light concentration units 114 in a relatively concentrated manner, which helps to enhance the degree of light concentration. In addition, in some embodiments, a component or film layer capable of blocking water vapor may be further disposed in the display device 100, where the component or film layer capable of blocking water vapor is, for example, alternately stacked with silicon nitride (SiNₓ) and indium tin oxide (TIO). In some embodiments, the component or film layer capable of blocking water vapor may be located between the light-transmitting layer 118 and the light concentration unit 114 or on the light concentration unit 114.

In FIG. 1, the light concentration unit 114 is separated from the light adjustment structure 130 by a required gap G. The thickness of the gap G is roughly equal to the focal length of the light control unit 132, which prevents the light shape from changing after the light emitted by the display panel 110 passes through the light control unit 132, and is conducive to clearly distinguishing the light emitted by each light emitting unit 112. For example, 0.8 times the focal length of the light control unit 132 may be less than or equal to the thickness of the gap G, and the thickness of the gap G is less than or equal to 1.2 times the focal length of the light control unit 132. In some embodiments, the thickness of the gap G is equal to the focal length of light control unit 132. In order to establish a sufficient gap G, the display device 100 also optionally includes a transparent layer 140. The transparent layer 140 is disposed between the display panel 110 and the light adjustment structure 130. The material of the transparent layer 140 includes glass, plastic, adhesive materials (optical adhesive, light-transmitting resin, etc.), and other materials that are transparent to the wavelength range of light emitted by the light emitting unit 112 (such as the visible light range, but not limited thereto), or a combination of the above. The transparent layer may be, for example, a single layer or a multi-layer architecture. In some embodiments, a thickness T140 of the transparent layer 140 may be greater than a thickness T116B of the second substrate 116B, but is not limited thereto. In some embodiments, the transparent layer 140 and the second substrate 116B may have the same material, but are two independent components. In some embodiments, second substrate 116B is thick enough to provide the gap G, then transparent layer 140 may be omitted. At this time, the light adjustment structure 130 can be directly disposed on the second substrate 116B.

The image displayed by the display panel 110 is composed of light provided by the light emitting unit 112. The light emitting units 112 disposed on the first substrate 116A probably generate heat when they emit light (operate). When the heat is too high, the light emitting unit 112 may be inefficient or damaged, and may even cause damage to the driving structure or circuits surrounding the light emitting unit 112. Under the condition that the light emitting unit 112 provides higher brightness lighting conditions, the problem of heat becomes even more significant. Here, the heat dissipation element 120 is disposed adjacent to the first substrate 116A, so that the heat generated by the light emitting unit 112 on the first substrate 116A during operation can be effectively dissipated. For example, the heat dissipation element 120 is disposed on the back side of the first substrate 116A, that is, on the non-light emitting side 110B of the display panel 110. Under the setting of the heat dissipation element 120, the heat emitted by the light emitting unit 112 can be dissipated more easily, allowing the light emitting unit 112 to operate with high-brightness luminous efficiency without being easily damaged. Therefore, the display device 100 can be used to provide a high-brightness display image while still maintaining an ideal service life.

In some embodiments, the heat dissipation element 120 may include an active heat dissipation element. The active heat dissipation element is a component that can be controlled to provide and/or regulate heat dissipation. For example, the active heat dissipation element can be controlled to be turned on or off. In some embodiments, the active heat dissipation element can also be further controlled to provide different degrees of heat dissipation. The active heat dissipation element can include active elements, such as a combination of fans, motors, and heat pipes. In some embodiments, the heat dissipation element 120 may include a passive heat dissipation element, such as a heat sink fin, a heat sink, a combination thereof, or the like. In some embodiments, the heat dissipation element 120 can be directly attached to the back of the display panel 110 (that is, the side of the first substrate 116A opposite to the light emitting unit 112). For example, the display device 100 may further include an adhesive layer disposed between the back (the non-light emitting side) of the display panel 110 and the heat dissipation element 120. Through the design of the adhesive layer, the heat dissipation element can be directly attached to the back of the display panel 110 to enhance the heat dissipation effect. In some embodiments, the heat dissipation element 120 may include an active heat dissipation element, a passive heat dissipation element, or a combination of the above.

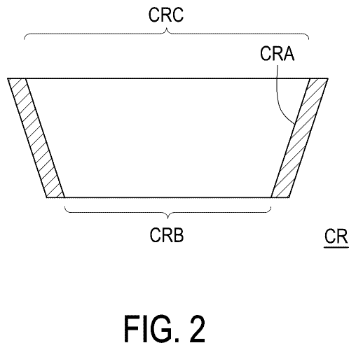

In FIG. 1, the light concentration unit 114 of the display panel 110 is represented by having a convex lens-shaped cross-sectional structure facing the light emitting unit 112, that is, the center portion of the individual light concentration unit 114 (e.g., the center portion of the arc profile) is closer to a corresponding light emitting unit 112, and an edge portion (e.g., the edge portion of the arc profile) is further away from a corresponding light emitting unit 112, but the disclosure is not limited thereto. In some embodiments, the light concentration units 114 of the display panel 110 may have a convex lens-shaped cross-sectional structure facing away from the light emitting unit 112, that is, the center portion of the individual light concentration unit 114 (e.g., the center portion of the arc profile) is further away from a corresponding light emitting unit 112, and the edge portion (e.g., the edge portion of the arc profile) is closer to the corresponding light emitting unit 112. In some embodiments, the light concentration unit 114 of the display panel 110 may have a multi-column structure (e.g., a meta lens). In some embodiments, the light concentration unit 114 of the display panel 110 may have a light cup structure CR as shown in FIG. 2, which can also be understood as a condenser reflector structure. The light cup structure CR has an inclined cup wall CRA, and a light entrance opening CRB of the light cup structure CR is smaller than a light exit opening CRC.

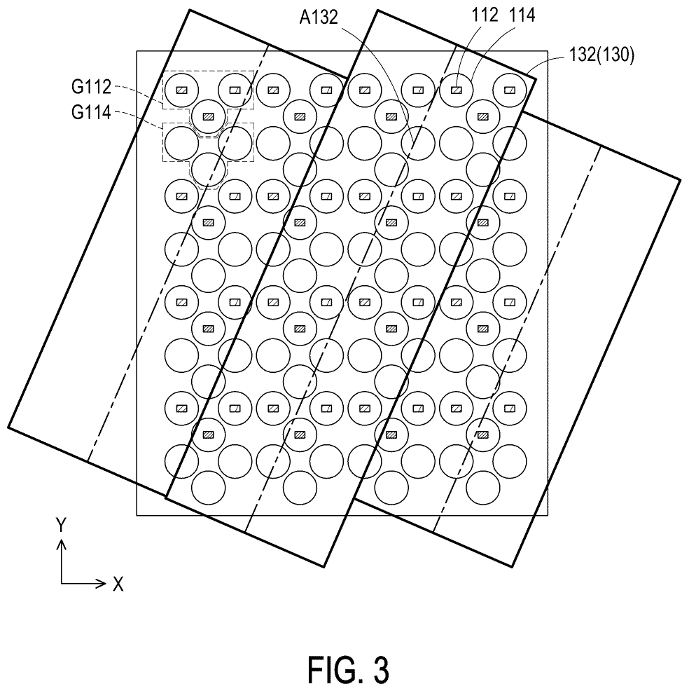

FIG. 3 is a schematic diagram of an arrangement relationship between a light emitting unit, a light concentration unit, and a light adjustment structure in the display device according to some embodiments of the disclosure. As shown in FIG. 3, in the display device of some embodiments of the disclosure, the display panel may include N light emitting units 112 and M light concentration units 114, where N and M are positive integers, and N may be less than M. Individual light emitting unit 112 is represented in FIG. 3 with a rectangular pattern, and individual light concentration unit 114 is represented in FIG. 3 with a circular pattern. The individual light concentration unit 114 may have a hemispherical (lens)-shaped structure, but is not limited thereto. In some embodiments, several of the M light concentration units 114 are not disposed corresponding to the light emitting units 112, so there are no rectangular patterns within some circular patterns in FIG. 3. In some embodiments, M and N may also be equal.

In some embodiments, three light emitting units 112 may form a light emitting unit group G112, and the light emitting unit group G112 may be arranged in an array in a first direction X and a second direction Y. The light concentration unit 114 may correspond to the setting of the light emitting unit 112 to form a light concentration unit group G114 in a group of three, and the light concentration unit group G114 is arranged in an array in the first direction X and the second direction Y. The number of the light concentration unit groups G114 is greater than the number of the light emitting unit groups G112. Part of the light concentration unit group G114 is not disposed corresponding to the light emitting unit 112, such as the group labelled G114 in FIG. 3, but the disclosure is not limited thereto. Each of the N light emitting units 112 may be disposed corresponding to one of the M light concentration units 114. The light emitted by the light emitting unit 112 in the main light emitting angle range can be guided to the required « angle by the corresponding light concentration unit 114, where 0°≤α<90°. For example, the thickness direction Z represents α=0°. In some embodiments, each light emitting unit 112 may be positioned to align with the center of the corresponding light concentration unit 114. In this way, the light emitted by the light emitting unit 112 in the main light emitting angle range can pass through the light concentration unit 114 and is not easily bent, thereby achieving an ideal light concentration effect (e.g., light is concentrated in the thickness direction Z and emitted in the thickness direction Z). In some embodiments, each light emitting unit 112 may be configured to be offset by a specific distance relative to the center of the corresponding light concentration unit 114. In this way, the light emitted by the light emitting unit 112 in the main light emitting angle range can be guided to the angle a by the corresponding light concentration unit 114. At this time, 0°<α<90° (e.g., light is concentrated in a direction different from the original light emitting direction and emitted in this direction, where the angle between this direction and the thickness direction Z is α). Therefore, the corresponding relationship between the light emitting unit 112 and the light concentration unit 114 can be adjusted according to the required light effect (e.g., the light concentration and light emitting directions of the display panel 110).

In FIG. 3, the light adjustment structure 130 includes multiple light control units 132. Individual light control unit 132 may have a semi-cylindrical structure, such as a semi-circular cross-section as shown in FIG. 1, and is used to control the light traveling direction of the light emitting unit 112. From the perspective shown in FIG. 3, the individual light control unit 132 has an elongated shape and overlaps at least two of the light emitting units 112. In some embodiments, the individual light control unit 132 may overlap at least 2×2 (4) or more than 16 light emitting units 112. In some embodiments, the extension direction of a centerline A132 of the individual light control unit 132 intersects the first direction X and also intersects the second direction Y.

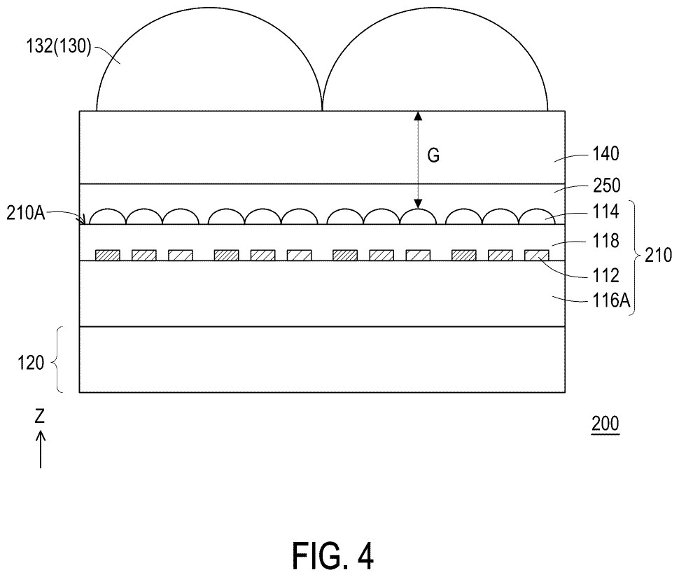

FIG. 4 is a partial cross-sectional schematic diagram of a display device according to an embodiment of the disclosure. A display device 200 of FIG. 4 is similar to the display device 100 of FIG. 1, and the same reference numerals in the two embodiments are used to indicate the same or equivalently replaceable components. Therefore, the descriptions and illustrations of components designated by the same reference numerals in these embodiments may be applied and referred to each other. The display device 200 includes a display panel 210, a heat dissipation element 120, a light adjustment structure 130, a transparent layer 140, and a light-transmitting layer 250, where the display panel 210 includes multiple light emitting units 112, multiple light concentration units 114, a first substrate 116A, and a light-transmitting layer 118. The display device 200 is different from the display device 100 mainly in that the structure of the display panel 210 of the display device 200 and the display device 200 additionally have a light-transmitting layer 250. In the display device 200, the settings and functions of the heat dissipation element 120 and the light adjustment structure 130 can be referred to FIG. 1 and its related description, and therefore are not repeated in the following. In addition, the configuration relationship between the light adjustment structure 130, the light concentration unit 114, and the light emitting unit 112 can be referred to FIG. 3 and its related description, and therefore are not repeated in the following.

In this embodiment, the display panel 210 includes multiple light emitting units 112, multiple light concentration units 114, a first substrate 116A, and a light-transmitting layer 118. The light emitting unit 112 is disposed on the first substrate 116A, the light-transmitting layer 118 is disposed on the first substrate 116A and around the light emitting unit 112, and the light concentration unit 114 is disposed on the light-transmitting layer 118. In some embodiments, the light emitting unit 112 and the light concentration unit 114 are disposed on opposite sides of the light-transmitting layer 118, and the light concentration unit 114 protrudes from the light-transmitting layer 118 without being buried in the light-transmitting layer 118. In this embodiment, the individual light concentration unit 114 may have a convex lens-shaped cross-sectional structure facing away from the light emitting unit 112. That is, the light exit surface of the individual light concentration unit 114 is further away from a corresponding light emitting unit 112 at the center portion (e.g., the center portion of the arc profile), and is closer to the corresponding light emitting unit 112 at the edge portion (e.g., the edge portion of the arc profile). However, this disclosure is not limited thereto.

The light-transmitting layer 250 is disposed between a light emitting side 210A of the display panel 210 and the transparent layer 140. The light-transmitting layer 250 and the transparent layer 140 are disposed between the light concentration unit 114 and the light adjustment structure 130. The light-transmitting layer 250 may be disposed around the light concentration unit 114, the light concentration unit 114 of the display panel 110 may be buried in the light-transmitting layer 250, and the transparent layer 140 may be disposed on the light-transmitting layer 250. The material of the light-transmitting layer 250 can be the same as that of the light-transmitting layer 118. For example, the materials of the light-transmitting layer 250 and the light-transmitting layer 118 may include multiple layers/stacks of multiple materials, such as a combination including organic materials, photoresist materials, adhesive materials (optical adhesives, light-transmitting resins, etc.), low refractive index materials, etc. In some embodiments, the refractive index of the low refractive index material may be less than 1.4, but is not limited thereto.

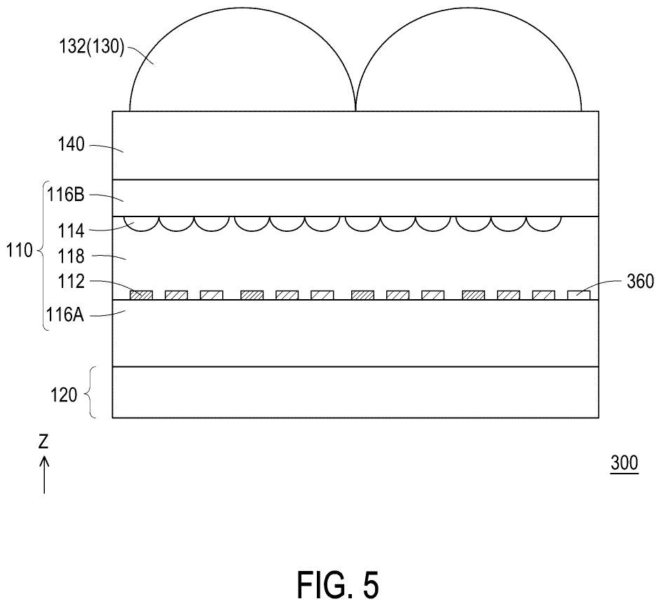

FIG. 5 is a partial cross-sectional schematic diagram of a display device according to an embodiment of the disclosure. A display device 300 of FIG. 5 is similar to the display device 100 of FIG. 1, and the same reference numerals in the two embodiments are used to indicate the same or equivalently replaceable components. Therefore, the descriptions and illustrations of components designated by the same reference numerals in these embodiments may be applied to each other. The display device 300 includes a display panel 110, a heat dissipation element 120, a light adjustment structure 130, a transparent layer 140, and a temperature sensor 360. Specifically, the display device 300 can be regarded as an implementation method of adding a temperature sensor 360 to the display device 100. Therefore, the relevant descriptions of the display device 100 can be applied to the display device 300.

The temperature sensor 360 is disposed on the first substrate 116A of the display panel 110 and is located between the first substrate 116A and the light-transmitting layer 118. In some embodiments, although not shown in FIG. 5, the first substrate 116A may include a substrate body and a driving structure disposed on the substrate body. The temperature sensor 360 can be integrated into the driving structure. In some embodiments, the temperature sensor 360 may be composed of electronic components such as thin film transistors. The temperature sensor 360 can sense the temperature of the display panel. For example, the temperature sensor 360 can be disposed near the light emitting unit 112 to sense temperature changes caused by the light emitting unit 112 emitting light. In some embodiments, the number and location of the temperature sensors 360 can be disposed according to different requirements. In other words, the quantity of temperature sensor 360 may be singular or plural, and the temperature sensor 360 may be disposed near the center or at the edge. In addition, the temperature sensor 360 in FIG. 5 can also be disposed in the display device 200 in FIG. 4 to achieve real-time, local temperature sensing.

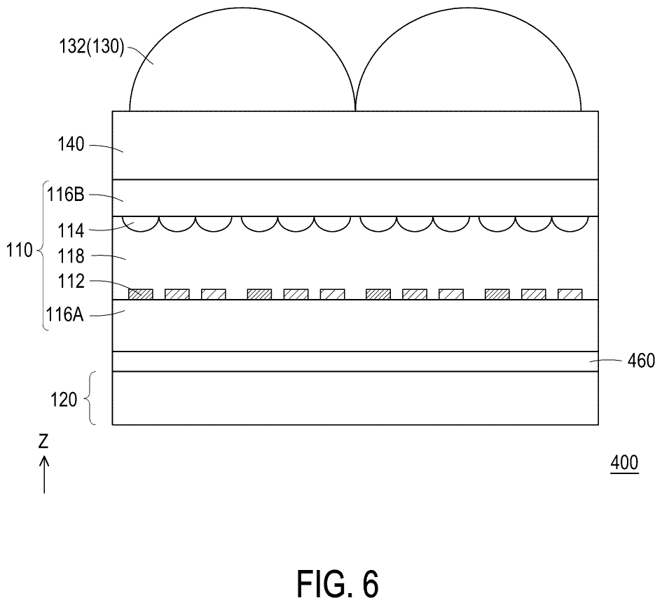

FIG. 6 is a partial cross-sectional schematic diagram of a display device according to an embodiment of the disclosure. A display device 400 of FIG. 6 is similar to the display device 100 of FIG. 1, and the same reference numerals in the two embodiments are used to indicate the same or equivalently replaceable components. Therefore, the descriptions and illustrations of components designated by the same reference numerals in these embodiments may be applied to each other. The display device 400 includes a display panel 110, a heat dissipation element 120, a light adjustment structure 130, a transparent layer 140, and a temperature sensor 460. Specifically, the display device 400 can be regarded as an implementation method of adding a temperature sensor 460 to the display device 100. Therefore, the relevant descriptions of the display device 100 can be applied to the display device 400. The temperature sensor 460 is disposed between the display panel 110 and the heat dissipation element 120. The temperature sensor 460 may be an external sensor. The temperature sensor 460 can sense temperature changes caused by the light emitting unit 112 emitting light. The temperature sensor 460 in FIG. 6 can also be disposed in the display device 200 in FIG. 4.

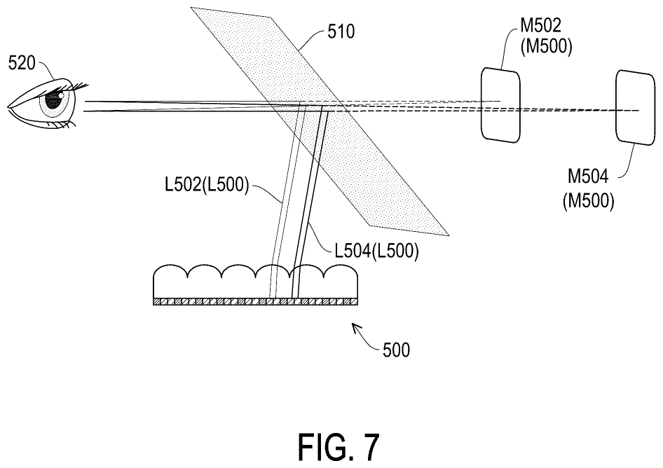

FIG. 7 is a schematic diagram of the application of display device in this disclosure. FIG. 7 shows the application of the display device 500 in augmented reality. In FIG. 7, the display device 500 may include the specific design of any one of the display devices 100 to 400 and any display device that can be equivalently substituted. Therefore, FIG. 7 can be regarded as an application of any one of the display devices 100 to 400, but is not limited thereto. The display device 500 may be a head-up display (HUD) device, but is not limited thereto. The display device 500 can be disposed on one side of a screen 510. The display device 500 may provide display light L500 emitted toward the screen 510, and the screen 510 may be tilted relative to the traveling direction of the display light L500. After the display light L500 is projected on the screen 510, an image M500 can be formed in the visual field direction of a user 520. In some embodiments, the display device 500 may be installed in a vehicle, and the screen 510 may be the windshield of the vehicle. In some embodiments, the display device 500 may be mounted on a motorcycle or similar vehicle body, and the screen 510 may be a windshield for a helmet. When the user 520 is driving a vehicle or a motorcycle, the user 520 can directly view the image M500 provided by the display device 500 without adjusting the angle of the head (such as lowering the head). The image M500 can provide instrument information, navigation information, and other information required for driving, allowing the user 520 to view the external environment (such as road conditions) outside the screen 510 while also seeing the information required for driving, which helps to improve driving safety.

In some embodiments, the display device 500 has the light adjustment structure 130 described in the foregoing embodiments, which controls the traveling direction and/or focal length of the display light L500. For example, the display light L500 may include display light L502 and display light L504. In some embodiments, the display light L502 and the display light L504 may provide different image information and/or focus toward different focus distances. After the display light L502 and the display light L504 are projected onto the screen 510, an image M502 and an image M504 can be formed in the visual field direction of the user 520, so that the user 520 can experience three-dimensional (3D), immersive reality, and/or images with different depths of field after receiving the image M502 and the image M504. In some embodiments, the focus distance of the image M502 and the image M504 can be adjusted according to different external conditions so that the display position, depth of field, and other display conditions of the image M502 and the image M504 can match the external environment, thereby providing a more optimized user experience. In addition, the display brightness of the display device 500 can also be adjusted according to the brightness of the external environment to ensure that the user 520 can clearly see the image M500. For example, the display brightness of the display device 500 in a strong light environment may be higher than the display brightness of the display device 500 in a weak light environment.

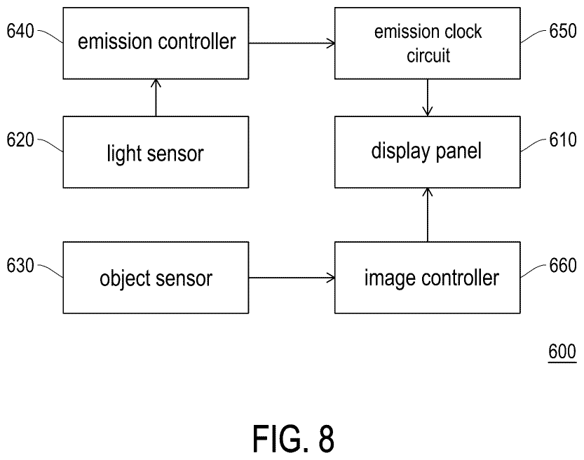

FIG. 8 is a block diagram of a display device according to an embodiment of the disclosure. A display device 600 in FIG. 8 includes a display panel 610, a light sensor 620, and an object sensor 630. The display panel 610 is used to display images. The light sensor 620 is used to sense ambient light and is electrically connected to the display panel 610. The display panel 610 can adjust the brightness of the display panel 610 according to the sensed ambient light. The object sensor 630 is used to sense objects in the environment, and the display panel 610 can adjust the image content of the display panel 610 according to the sensed environmental objects. In some embodiments, the ambient light intensity affects whether the user can clearly see the display image of the display panel 610. Therefore, the display device 600 can use the light sensor 620 to sense the ambient light intensity to adjust the brightness of the display image to achieve a good display effect. Additionally, in some embodiments, the display device 600 may be applied to a head-up display of a vehicle. When a vehicle is moving, the types and positions of surrounding objects change at any time. In order to coordinate the displayed image with changes in surrounding objects, the display device 600 can adjust the state of the displayed image (such as the depth of field of the image) according to the conditions of the surrounding objects sensed by the object sensor 630 to provide a good display effect. Here, the display device 600 may have the specific design of any one of the display devices 100 to 400 and any equivalent and alternative implementation. The light sensor 620 and the object sensor 630 in the display device 600 can be external sensors, or can be integrated with the display panel 610.

The display device 600 also includes an emission controller 640 and an emission clock circuit 650 connected between the display panel 610 and the light sensor 620. The emission clock circuit 650 may include chips and integrated circuits, but is not limited thereto. After sensing the ambient light, the light sensor 620 can provide a corresponding signal to the emission controller 640. The emission controller 640 can provide a corresponding control signal to the emission clock circuit 650 in response to the signal of the light sensor 620, and the emission clock circuit 650 can control the emission time duty ratio of the light emitting unit in the display panel 610, thereby controlling the emission time of the light emitting unit.

For example, when the light sensor 620 senses strong external light, the display brightness needs to be increased so that the user can see a clear image. At this time, the emission controller 640 can respond to the sensing result of the light sensor 620 and provide a control signal for increasing the emission time to the emission clock circuit 650, and the emission clock circuit 650 may, based on the control signal from the emission controller 640, allow the light emitting units of the display panel 610 to emit light for a longer period of time to display a brighter image. On the contrary, when the light sensor 620 senses weak external light, excessive image brightness may easily cause visual fatigue to the user and affect the line of sight of the user. Therefore, the light emitting controller 640 can respond to the sensing result of the light sensor 620 and provide a control signal for reducing the light emitting time to the emission clock circuit 650, so that the light emitting unit of the display panel 610 displays with a shorter light emitting time.

In addition, the display device 600 may also include an image controller 660. The image controller 660 can be electrically connected to the object sensor 630 and the display panel 610. The object sensor 630 may include a light radar (liDAR), camera, or the like in some embodiments. The object sensor 630 can identify surrounding objects, such as surrounding pedestrians, vehicles, lanes, road corners, or other objects on the road. When the object sensor 630 senses a specific object, it can provide the corresponding sensing result or signal to the image controller 660. The image controller 660 can adjust the image content to be displayed based on the received object sensing result or signal (e.g., adjusting the image depth of field or image display position, etc.) to provide the image to be displayed at a suitable depth of field. In this way, the display device 600 can not only provide clear images according to the brightness changes of the environment, but also display desired three-dimensional images according to the objects in the environment.

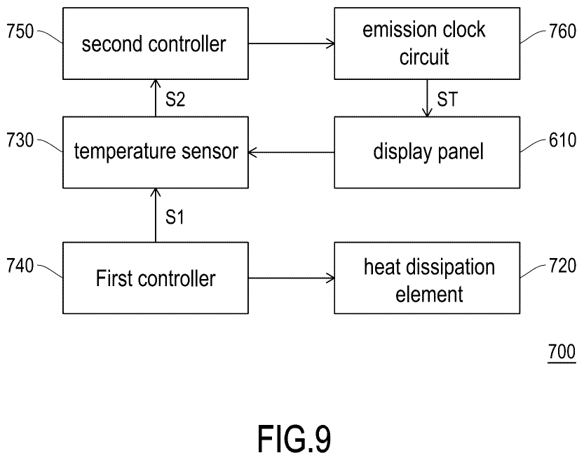

FIG. 9 is a block diagram of a display device according to an embodiment of the disclosure. A display device 700 in FIG. 9 mainly includes a display panel 610, a heat dissipation element 720, a temperature sensor 730, a first controller 740, and a second controller 750. The display panel 610 has multiple light emitting units, which can emit light to implement display functions. The temperature sensor 730 is used to sense the temperature of the display panel 610. In some embodiments, the temperature sensor 730 can be integrated into the display panel 610, such as the display device 300. In some embodiments, the temperature sensor 730 may be disposed between the display panel 610 and the heat dissipation element 720, such as the display device 400. The heat dissipation element 720 can be disposed adjacent to the display panel 610 to provide heat dissipation as needed to dissipate the heat generated by the display panel 610. In addition, the first controller 740 is used to control the heat dissipation element 720, and the second controller 750 is used to control the display panel 610.

The display panel 610 generates heat during display, and the longer the lighting time or the higher the lighting current of the light emitting unit, the more heat is generated. Under continuous heat generation, the light emitting unit or its surrounding circuits are easily damaged due to overheating. Therefore, the display device 700 uses the temperature sensor 730 to sense the temperature of the display panel 610, and the display device 700 can control the heat dissipation function of the heat dissipation element 720 and adjust the display brightness of the display panel 610 in response to the sensing result of the temperature sensor 730. For example, the temperature sensor 730 may provide a first signal S1 to the first controller 740 and a second signal S2 to the second controller 750 according to the sensed temperature. The first controller 740 controls the heat dissipation work of the heat dissipation element 720 in response to the first signal S1. The second controller 750 adjusts the display brightness of the display panel 610 in response to the second signal S2.

Specifically, the first controller 740 is, for example, a heat dissipation element controller, which is disposed between the heat dissipation element 720 and the temperature sensor 730. The first controller 740 can control the heat dissipation operation of the heat dissipation element 720 in response to the first signal S1 provided by the temperature sensor 730. For example, if the first signal S1 of the temperature sensor 730 indicates that the sensing result is high temperature, the first controller 740 can send a corresponding control signal to improve the heat dissipation efficiency of the heat dissipation element 720. In some embodiments, the heat dissipation element 720 is a fan, and turning on the fan or accelerating the fan speed can improve the heat dissipation efficiency of the heat dissipation element 720. In some embodiments, the heat dissipation element 720 is a heat dissipation pipe, and initiating the flow of heat dissipation fluid within the heat pipe or accelerating the flow of heat dissipation fluid within the heat pipe may enhance the heat dissipation efficiency of the heat dissipation element 720.

In addition, the display device 700 also includes an emission clock circuit 760, and the emission clock circuit 760 is electrically connected to the second controller 750 and the display panel 610. The second controller 750 is, for example, an emission controller, and is connected between the temperature sensor 730 and the emission clock circuit 760. When the second signal S2 of the temperature sensor 730 indicates that the temperature of the display panel 610 is high, the second controller 750 can provide a corresponding control signal to the emission clock circuit 760 based on the second signal S2, and the emission clock circuit 760 can provide an adjusted emission time duty ratio signal ST to the display panel 610 to regulate the display brightness of the display panel 610. In this way, the heating generation of the light emitting unit can be regulated, preventing malfunction or damage due to overheating.

Overall, when the temperature sensor 730 senses a high temperature result, the first controller 740 can control the heat dissipation element 720 to provide heat dissipation to reduce the temperature of the display panel 610, and at the same time, the second controller 750 can control the display brightness of the display panel 610 to reduce heating. Therefore, the display device 700 is not prone to failure or damage due to overheating and has ideal service life and efficiency. In some embodiments, when the temperature sensor 730 senses a high temperature result, the first controller 740 and the second controller 750 may operate selectively, alternately, or simultaneously to maintain good performance of the display device 700 and avoid damage and/or malfunction due to overheating. In addition, in some embodiments, the heat dissipation element 720 can be a passive heat dissipation structure such as a heat sink or a heat sink fin, which does not need to be controlled to provide heat dissipation, so the first controller 740 can be omitted.

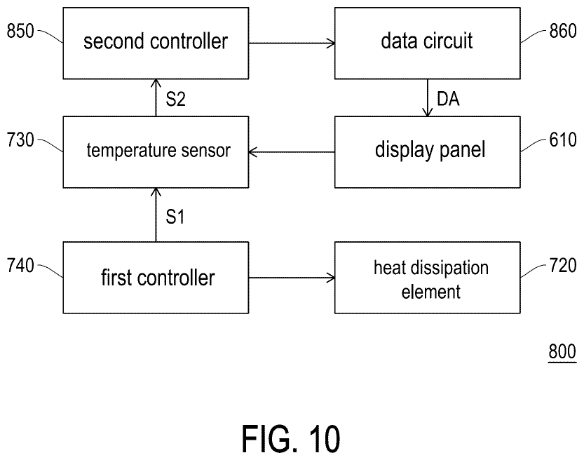

FIG. 10 is a block diagram of a display device according to an embodiment of the disclosure. The display device 700 in FIG. 10 mainly includes a display panel 610, a heat dissipation element 720, a temperature sensor 730, a first controller 740, and a second controller 850. The display panel 610 has multiple light emitting units, which can emit light to implement display functions. The temperature sensor 730 is used to sense the temperature of the display panel 610. The heat dissipation element 720 can be disposed adjacent to the display panel 610 to dissipate the heat generated by the display panel 610. In some embodiments, the temperature sensor 730 can be integrated into the display panel 610, such as the display device 300. In some embodiments, the temperature sensor 730 may be disposed between the display panel 610 and the heat dissipation element 720, such as the display device 400. In addition, the first controller 740 is used to control the heat dissipation element 720, and the second controller 850 is used to control the display panel 610.

Similar to the display device 700, the display device 800 uses the temperature sensor 730 to sense the temperature of the display panel 610, and the display device 800 can control the heat dissipation function of the heat dissipation element 720 and regulate the display brightness of the display panel 610 in response to the sensing result of the temperature sensor 730. For example, the temperature sensor 730 may provide a first signal S1 to the first controller 740 and a second signal S2 to the second controller 850 according to the sensed temperature. The first controller 740 controls the heat dissipation work of the heat dissipation element 720 in response to the first signal S1. The second controller 850 regulates the display brightness of the display panel 610 in response to the second signal S2. In this embodiment, the functions and structures of the display panel 610, the heat dissipation element 720, the temperature sensor 730, and the first controller 740 can be referred to the display device 700 in FIG. 9, and therefore are not be repeated in the following.

In this embodiment, the second controller 850 is, for example, a voltage controller (e.g., a gamma voltage controller), and the display device 800 also includes a data circuit 860. The data circuit 860 may include a chip or an integrated circuit, but is not limited thereto. The data circuit 860 is electrically connected to the second controller 850 and the display panel 610, where the data circuit 860 is used to provide a data signal DA to the display panel 610 to regulate the display brightness of the display panel 610. For example, when the second signal S2 provided by the temperature sensor 730 indicates that the temperature of the display panel 610 is high, the second controller 850 can send a corresponding control signal to the data circuit 860 to regulate the display brightness of the display panel 610. For example, the data signal DA provided by the data circuit 860 can reduce the current level of the light emitting unit, thereby reducing the heating condition of the light emitting unit. In other words, the second controller 850 and the data circuit 860 of this embodiment can reduce the heating phenomenon by reducing the current flowing through the light emitting unit. In comparison, the operation of the second controller 750 and the emission clock circuit 760 of the display device 700 in FIG. 9 is to reduce the heating condition by reducing the emission time of the light emitting unit by changing the emission time duty ratio of the light emitting unit.

In some embodiments, the operation modes of the second controller 850 and the data circuit 860 and the operation modes of the second controller 750 and the emission clock circuit 760 can be applied comprehensively to regulate the display brightness of the display panel 610 and control the heating condition. In addition, the light sensor 620 and the object sensor 630 in the display device 600 can also be integrated into the display device 700 or the display device 800 to provide required display functions. For example, when the light sensor 620 senses that the ambient light increases, the display brightness of the display panel 610 can be regulated to increase. At this time, the heat generated by the display panel 610 may also increase. After sensing the temperature rise, the temperature sensor 730 can provide the first signal S1 to the first controller 740 to control the heat dissipation element 720 to provide heat dissipation or enhance heat dissipation. At the same time, the temperature sensor 730 can provide the second signal S2 to the second controller 750 and/or the second controller 850 to further slow down the generation of heat by regulating the display brightness of the display panel 610.

In some embodiments, the heat dissipation element 720 can be replaced by a passive heat dissipation structure (such as a heat sink, a heat sink fin), so the first controller 740 can be omitted, and only the second controller 750/850 regulates the temperature of the display panel 610 in response to the signal of the temperature sensor 730. In some embodiments, the light sensor 620 can be applied in the display devices 700 and 800, and the second controller 750/850 can receive the signal of the light sensor 620 to regulate the display brightness of the display panel 610. In some embodiments, the second controller 850 and the data circuit 860 can be used to replace the emission controller 640 and the emission clock circuit 650 in the display device 600 to regulate the display brightness of panel 610 according to the sensing result of the light sensor 620. In addition, the object sensor 630 can be applied in the display devices 700 and 800, and the display panel 610 can also adjust the image it presents according to the surrounding objects sensed by the object sensor 630 to provide good image quality. Furthermore, in the embodiments of FIG. 8 to FIG. 10, the structural configuration relationship between the display panel 610, the heat dissipation element 720, and the temperature sensor 730 can be implemented with reference to the embodiments of FIG. 1 to FIG. 6. The display devices described in FIG. 1 to FIG. 6 and FIG. 8 to FIG. 10 can be applied to the application environment of FIG. 7, and can also be applied to other application environments, and the disclosure is not limited thereto.

To sum up, the display device according to the embodiment of the disclosure has a heat dissipation structure on one side of the display panel, which can effectively dissipate the heat of the display panel through the heat dissipation effect of the heat dissipation structure, thereby reducing damage and failure caused by overheating in a high-efficiency display mode. In addition, the heat dissipation effect of the heat dissipation structure in the display device and the display conditions of the display panel can be controlled and regulated in response to the sensing results of the ambient light and/or the temperature change measurement results. Therefore, the display device can maintain the ideal display effect.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display device, comprising:
a display panel, having a light emitting side and a non-light emitting side, comprising a plurality of light emitting units and a plurality of light concentration units, wherein each of the light emitting units corresponds to one of the light concentration units;
a heat dissipation element, disposed on the non-light emitting side of the display panel; and
a light adjustment structure, disposed on the light emitting side of the display panel and comprising a plurality of light control units, wherein each of the light control units corresponds to at least two of the light emitting units.

2. The display device according to claim 1, comprising:
a temperature sensor, configured to sense a temperature of the display panel;
a first controller, configured to control the heat dissipation element; and
a second controller, configured to control the display panel;
wherein the temperature sensor provides a first signal to the first controller according to the temperature, and provides a second signal to the second controller.

3. The display device according to claim 2, comprising:
an emission clock circuit, electrically connected to the second controller and the display panel, wherein the emission clock circuit is configured to provide an emission time duty ratio signal to the display panel to regulate a display brightness of the display panel.

4. The display device according to claim 1, comprising:
a data circuit, electrically connected to the second controller and the display panel, wherein the data circuit is configured to provide a data signal to the display panel to regulate a brightness of the display panel.

5. The display device according to claim 2, wherein the temperature sensor is disposed between the display panel and the heat dissipation element.

6. The display device according to claim 2, wherein the display panel comprises a first substrate, wherein the light emitting units and the temperature sensor are disposed on the first substrate.

7. The display device according to claim 1, wherein the heat dissipation element comprises an active heat dissipation element.

8. The display device according to claim 1, comprising:
a light sensor, electrically connected to the display panel and configured to sense ambient light, the display panel regulating a brightness of the display panel according to the ambient light.

9. The display device according to claim 1, comprising:
an adhesive layer, disposed between the non-light emitting side of the display panel and the heat dissipation element.

10. The display device according to claim 1, comprising:
a light-transmitting layer, disposed between the light emitting units and the light concentration units.

11. The display device according to claim 10, wherein a refractive index of the light-transmitting layer is less than a refractive index of the light concentration units.

12. The display device according to claim 10, wherein a difference between a refractive index of the light-transmitting layer and a refractive index of the light concentration units is greater than 0.5.

13. The display device according to claim 10, wherein a refractive index of the light-transmitting layer is less than 1.4.

14. The display device according to claim 1, comprising:
a transparent layer, disposed between the display panel and the light adjustment structure.

15. The display device according to claim 1, wherein the display panel further comprises a first substrate and a second substrate, the light emitting units are disposed on the first substrate, and the light concentration units are disposed on the second substrate.

16. The display device according to claim 15, further comprising a transparent layer disposed between the second substrate and the light adjustment structure.

17. The display device according to claim 16, wherein a thickness of the transparent layer is greater than the second substrate.

18. The display device according to claim 1, wherein a number of the light emitting units is less than a number of the light concentration units.

19. The display device according to claim 1, wherein the light emitting units comprise a light emitting diode.

20. The display device according to claim 1, wherein each of the light concentration units comprises a lens, a meta lens, a condenser reflector, or a combination of the above.
